(19) United States
(12) Patent Application Publication
(10) Pub. No.: US 2023/0284480 A1
(43) Pub. Date: Sep. 7, 2023

(54) ELECTRONIC DEVICE

(71) Applicant: Samsung Display Co., Ltd., Yongin-si (KR)

(72) Inventors: MYOUNGJIN PARK, Hwaseong-si (KR); JINGOO KANG, Suwon-si (KR); SEHUN KIM, Yongin-si (KR); YOUNGIL KIM, Hwaseong-si (KR); JUYON LEE, Cheonan-si (KR)

(21) Appl. No.: 18/067,543

(22) Filed: Dec. 16, 2022

(30) Foreign Application Priority Data
Mar. 4, 2022 (KR) 10-2022-0028399

(51) Int. Cl. H10K 59/122; H10K 50/15; H10K 50/16; H10K 50/115; H10K 50/125; H10K 59/38; H10K 50/17; H10K 85/60; C09K 11/67; C09K 11/66; C09K 11/60; C09K 11/57

(52) U.S. Cl. CPC H10K 59/122; H10K 50/15; H10K 50/16; H10K 50/115; H10K 50/125; H10K 59/38; H10K 50/171; H10K 85/60; C09K 11/671; C09K 11/662; C09K 11/605; C09K 11/574

(57) ABSTRACT

An electronic device including first to third light emitting regions and a dummy region is provided. The electronic device includes a base layer, and a display element layer including a pixel defining film on the base layer, light emitting elements divided by the pixel defining film, and a reduction preventing layer containing a reduction preventing agent, and the light emitting elements each include an electron transport region containing a metal oxide. The electronic device may have improved electron transport function of the electron transport region by the reduction preventing agent contained in the reduction preventing layer, thereby improving the luminous efficiency.

### CROSS-REFERENCE TO RELATED APPLICATION

This application claims priority to and the benefit of Korean Patent Application No. 10-2022-0028399, filed on Mar. 4, 2022, the entire content of which is hereby incorporated by reference.

### BACKGROUND

### 1. Field

Aspects of one or more embodiments of the present disclosure relate to an electronic device including a reduction preventing layer.

### 1. Description of the Related Art

Various electronic devices utilized in multimedia devices, such as a television, a mobile phone, a tablet computer, a navigation device, and/or a game console, are being developed. Such electronic devices utilize a self-luminescent display element which implements display by causing a luminescent material including an organic compound to emit light.

Development of a light emitting element utilizing quantum dots as a light emitting material is underway in an effort to enhance the color reproducibility of electronic devices, and there is also a demand for increasing the luminous efficiency and service life of a light emitting element utilizing quantum dots.

### SUMMARY

An aspect of one or more embodiments of the present disclosure is directed toward an electronic device including a reduction preventing layer and having improved luminous efficiency.

Additional aspects will be set forth in part in the description which follows and, in part, will be apparent from the description, or may be learned by practice of the presented embodiments of the disclosure.

An embodiment of the present disclosure provides an electronic device including first to third light emitting regions, and a dummy region, wherein the electronic device includes a base layer, and a display element layer including a pixel defining film on the base layer, first to third light emitting elements which are divided (e.g., defined) by the pixel defining film and disposed corresponding to the first to third light emitting regions, respectively, and a reduction preventing layer which is disposed corresponding to the dummy region and contains a reduction preventing agent, wherein the first to third light emitting elements each include a first electrode, a second electrode on the first electrode, a hole transport region between the first electrode and the second electrode, and an electron transport region which is between the hole transport region and the second electrode and contains a metal oxide, wherein the first light emitting element includes a first emission layer including a first quantum dot between the hole transport region and the electron transport region, the second light emitting element includes a second emission layer including a second quantum dot between the hole transport region and the electron transport region, and the third light emitting element includes a third emission layer including a third quantum dot between the hole transport region and the electron transport region.

In an embodiment, the reduction preventing agent may be represented by Formula 1 or Formula 2.

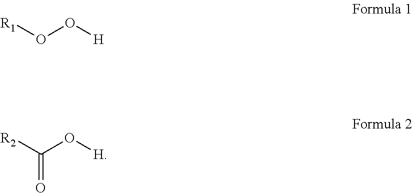

In Formula 1, R₁ may be a substituted or unsubstituted alkyl group having 1 to 20 carbon atoms, or a substituted or unsubstituted aryl group having 6 to 30 ring-forming carbon atoms, and

in Formula 2, R₂ may be a substituted or unsubstituted alkyl group having 1 to 20 carbon atoms, or a substituted or unsubstituted aryl group having 6 to 30 ring-forming carbon atoms.

In an embodiment, the reduction preventing agent may be represented by any one selected from among compounds in Compound Group 1:

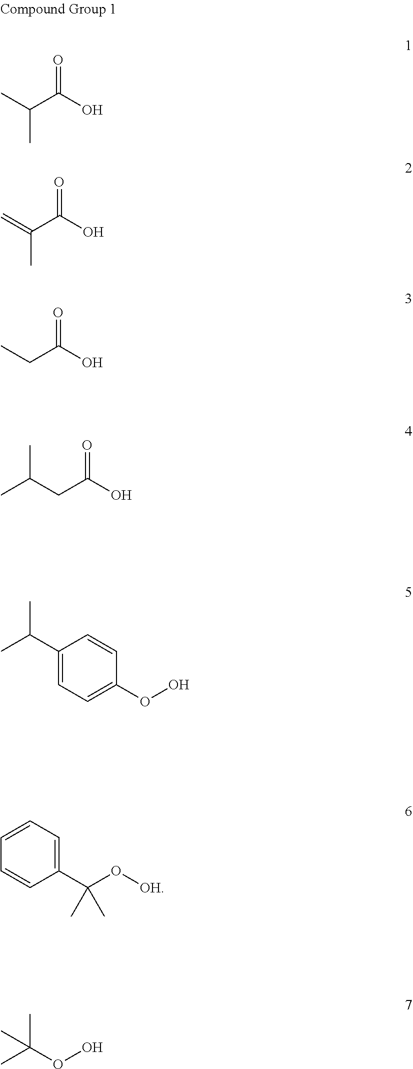

In an embodiment, the metal oxide may be represented by Formula 3:

M₁₍ₓ₎O_{(y)} Formula 3

In Formula 3, M₁ may be any one selected from among Zn, Ti, Zr, Sn, W, Ta, Ni, Mo, and Cu, and x and y may each independently be an integer from 1 to 5.

In an embodiment, the metal oxide may be represented by Formula 4:

Zn_{(1-z)}M_{2(z)}O Formula 4

In Formula 4, M2 may be any one selected from among Mg, Co, Ni, Zr, Mn, Sn, Y, and Al, and z may be 0 to 0.5.

In an embodiment, the metal oxide may include at least one of ZnO, ZnMgO, MoO₃, NiOₓ, TiO₂, SnO₂, or Cu₂O.

In an embodiment, when viewed in a plane (in a plan view), the dummy region may be adjacent to the first light emitting region in a first direction, and may be adjacent to the second light emitting region in a second direction perpendicular to the first direction.

In an embodiment, when viewed in a plane (in a plan view), the area of the dummy region may be smaller than the areas of the second light emitting region and the third light emitting region.

In an embodiment, the first emission layer may emit red light, the second emission layer may emit green light, and the third emission layer may emit blue light.

In an embodiment, the electronic device may further include a light control layer on the display element layer, wherein the light control layer includes a first filter transmitting the red light, a second filter which is disposed overlapping the second emission layer and transmits the green light, and a third filter which is disposed overlapping the third emission layer and transmits the blue light.

In an embodiment, the reduction preventing layer may include about 0.05 vol % to about 0.10 vol % of the reduction preventing agent with respect to a total volume of the reduction preventing layer.

In an embodiment, the reduction preventing agent may contain a hydrogen atom at the end (of the agent) thereof, the metal oxide may contain an oxygen atom on the surface thereof, and the oxygen atom may be bonded to the hydrogen atom.

In an embodiment of the present disclosure, an electronic device including a base layer, and a display element layer including a pixel defining film on the base layer, a light emitting element divided by the pixel defining film, and a reduction preventing layer containing a reduction preventing agent containing a hydrogen atom, wherein the light emitting element includes a first electrode, a second electrode on the first electrode, a hole transport region between the first electrode and the second electrode, an emission layer which is between the hole transport region and the second electrode and includes a quantum dot, and an electron transport region which is between the emission layer and the second electrode and contains a metal oxide containing an oxygen atom on the surface thereof.

In an embodiment, the reduction preventing agent may be represented by Formula 1 or Formula 2.

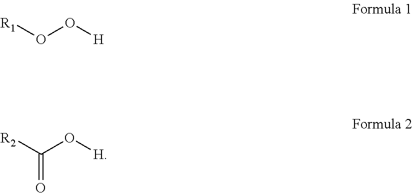

In Formula 1, R₁ may be a substituted or unsubstituted alkyl group having 1 to 20 carbon atoms, or a substituted or unsubstituted aryl group having 6 to 30 ring-forming carbon atoms, and

in Formula 2, R₂ may be a substituted or unsubstituted alkyl group having 1 to 20 carbon atoms, or a substituted or unsubstituted aryl group having 6 to 30 ring-forming carbon atoms.

In an embodiment, the reduction preventing agent may be represented by any one selected from among compounds in Compound Group 1:

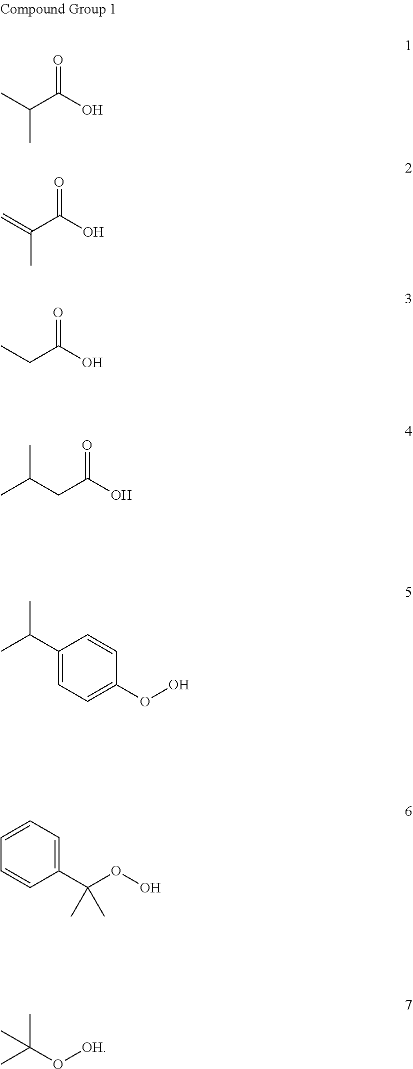

In an embodiment, the metal oxide may be represented by Formula 3:

M₁₍ₓ₎O_{(y)} Formula 3

In Formula 3, M₁ may be any one selected from among Zn, Ti, Zr, Sn, W, Ta, Ni, Mo, and Cu, and x and y may each independently be an integer from 0 to 5.

In an embodiment, the metal oxide may be represented by Formula 4:

Zn_{(1-z)}M_{2(z)}O Formula 4

In Formula 4, M₂ may be any one selected from among Mg, Co, Ni, Zr, Mn, Sn, Y, and Al, and z may be 0 to 0.5.

In an embodiment, the metal oxide may include at least one of ZnO, ZnMgO, MoO₃, NiOₓ, TiO₂, SnO₂, or Cu₂O.

In an embodiment, the electron transport region may include an electron transport layer adjacent to the emission layer and an electron injection layer on the electron transport layer, wherein at least one of the electron transport layer or the electron injection layer may contain the metal oxide to which the hydrogen atom is bonded.

In an embodiment, the electron transport region may contain a metal oxide in which the hydrogen atom is bonded to the oxygen atom.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure. In the drawings:

FIG. 1 is a perspective view illustrating an electronic device according to an embodiment;

FIG. 2 is an exploded perspective view illustrating an electronic device according to an embodiment;

FIG. 3 is a cross-sectional view illustrating the electronic device according to an embodiment;

FIG. 4 is a plan view illustrating a portion of a display module according to an embodiment;

FIG. 5 is a cross-sectional view of a display module of an embodiment;

FIG. 6 is an enlarged view illustrating a portion of a reduction preventing layer according to an embodiment;

FIG. 7 is an enlarged view illustrating a portion of an electron transport region according to an embodiment;

FIG. 8 is a cross-sectional view schematically illustrating a light emitting element of an embodiment;

FIG. 9 is a graph showing a change in luminous efficiency over time of electronic devices of Example and Comparative Example; and

FIG. 10 is a graph showing a relative value of the luminous efficiency versus addition ratio of a reduction preventing agent contained in each of reduction preventing layers of electronic devices of Examples and Comparative Examples.

### DETAILED DESCRIPTION

The present disclosure may be modified in many alternate forms, and thus specific embodiments will be exemplified in the drawings and described in more detail. It should be understood, however, that it is not intended to limit the present disclosure to the particular forms disclosed, but rather, is intended to cover all modifications, equivalents, and alternatives falling within the spirit and scope of the present disclosure.

In the present disclosure, when an element (or a region, a layer, a portion, etc.) is referred to as being “on,” “connected to,” or “coupled to” another element, it refers to that the element may be directly disposed on/connected to/coupled to the other element, or that a third element may be disposed therebetween.

In some embodiments, in the present disclosure, “directly disposed” refers to that there is no layer, film, region, plate and/or the like added between a portion of a layer, a film, a region, a plate and/or the like and other portions. For example, “directly disposed” may refer to disposing without additional members such as an adhesive member between two layers or two members.

Like reference numerals refer to like elements. Also, in the drawings, the thicknesses, ratios, and dimensions of the components may be exaggerated for more effective description of technical contents.

The term “and/or” includes all combinations of one or more of which associated configurations may define.

It will be understood that, although the terms “first”, “second”, etc. may be utilized herein to describe one or more suitable components, these components should not be limited by these terms. These terms are merely utilized to distinguish one component from another. For example, a first component could be termed a second component, and, similarly, a second component could be termed a first component, without departing from the scope of the present disclosure. The terms of a singular form may include plural forms unless the context clearly indicates otherwise.

In some embodiments, terms such as “below,” “lower,” “above,” “upper,” and/or the like are utilized to describe the relationship of the configurations shown in the drawings. The terms are utilized as a relative concept and are described with reference to the direction indicated in the drawings. In the present disclosure, the expression “disposed on” may refer to the embodiment of being disposed on a lower portion of a member as well as the embodiment of being on an upper portion of a member.

Unless otherwise defined, all terms (including technical and scientific terms) utilized herein have the same meaning as commonly understood by one of ordinary skill in the art to which this present disclosure belongs. In some embodiments, it will be understood that terms, such as those defined in commonly utilized dictionaries, should be interpreted as having a meaning that is consistent with their meaning in the context of the relevant art and will not be interpreted in an idealized or overly formal sense unless expressly so defined herein.

It should be understood that the terms “include,” “have,” and/or the like are intended to specify the presence of stated features, integers, steps, operations, components, parts, or combinations thereof in the disclosure, but do not preclude the presence or addition of one or more other features, integers, steps, operations, components, parts, or combinations thereof.

Hereinafter, an electronic device according to an embodiment of the present disclosure will be described with reference to the accompanying drawings.

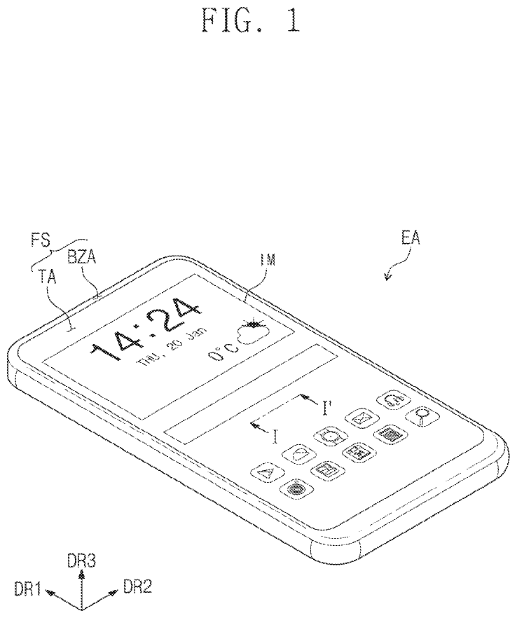

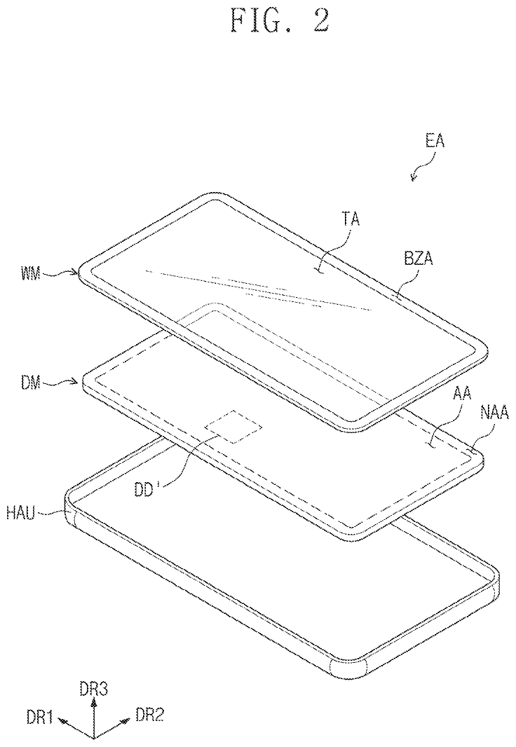

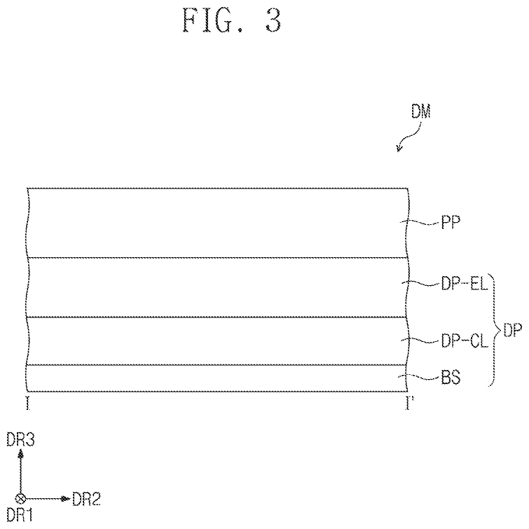

FIG. 1 is a perspective view illustrating an electronic device according to an embodiment. FIG. 2 is an exploded perspective view illustrating an electronic device according to an embodiment. FIG. 3 is a cross-sectional view illustrating a portion taken along line I-I′ of FIG. 1.

The electronic device EA of an embodiment illustrated in FIGS. 1 to 3 may be activated by an electrical signal. The electronic device EA may be a mobile phone, a tablet, a car navigation device, a game console, or a wearable device, but the embodiment of the present disclosure is not limited thereto. FIG. 1 illustrates that the electronic device EA is a mobile phone.

The electronic device EA may display an image IM through an active region ED-AA. The active region ED-AA may include a plane defined by a first direction axis DR1 and a second direction axis DR2. The active region ED-AA may further include a curved surface bent from at least one side of a plane defined by the first direction axis DR1 and the second direction axis DR2. For example, the active region ED-AA may include only the plane, and the active region ED-AA may further include four curved surfaces respectively bent from at least two or more, for example, four sides of the plane.

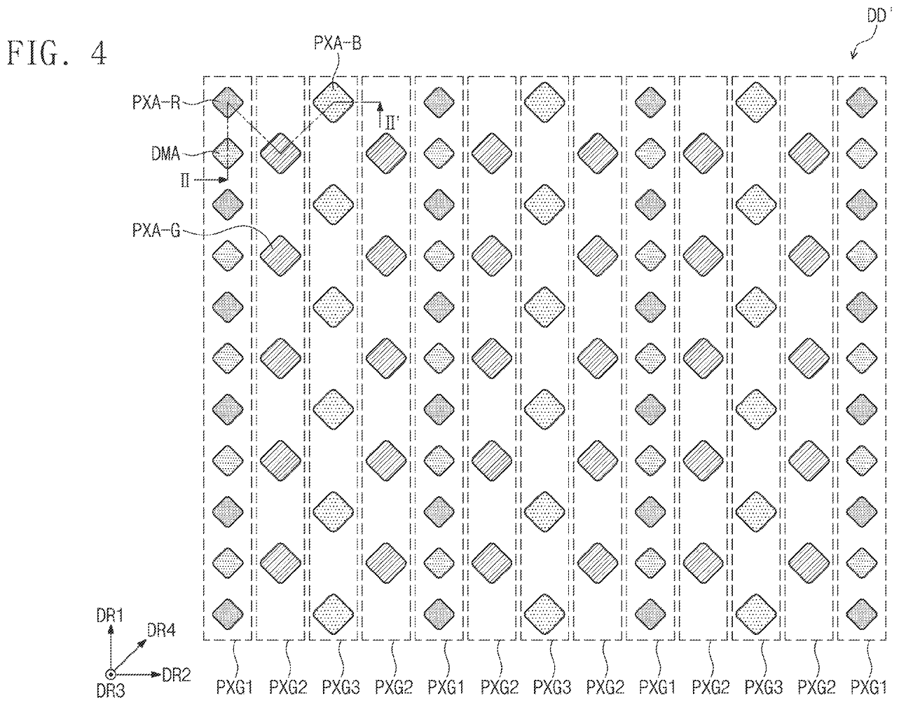

In some embodiments, FIG. 1 illustrates the first direction axis DR1 to a third direction axis DR3, and FIG. 4, which will be described below, further illustrates a fourth direction axis DR4. The directions indicated by the first to fourth direction axes DR1, DR2, DR3, and DR4 as described in the disclosure are relative concepts, and may thus be changed to other directions. In some embodiments, the directions indicated by the first to fourth direction axes DR1, DR2, DR3, and DR4 may be described as first to fourth directions, and the same reference symbols may be utilized.

In this disclosure, the first direction axis DR1 and the second direction axis DR2 are orthogonal to each other, and the third direction axis DR3 may be a normal line direction with respect to the plane defined by the first direction axis DR1 and the second direction axis DR2. The direction of the fourth direction axis DR4 may be a direction between the direction of the first direction axis DR1 and the direction of the second direction axis DR2.

Referring to FIG. 1, the electronic device EA may have a thickness direction parallel to the third direction axis DR3 that is the normal direction with respect to the plane defined by the first direction axis DR1 and the second direction axis DR2. In this disclosure, a front surface (or top surface) and a rear surface (or bottom surface) of members of the electronic device EA may be defined on the basis of the third direction axis DR3.

The image IM provided in the electronic device EA of an embodiment may include a still image as well as a dynamic image. In FIG. 1, as an example of the image IM, a watch window and icons are illustrated. A surface on which the image IM is displayed may correspond to a front surface of the electronic device EA and may correspond to a front surface of a window member WM.

In some embodiments, the electronic device EA according to an embodiment may detect user's inputs applied from the outside. The user's inputs include one or more suitable types (kinds) of external inputs such as a portion of user's body, light, heat, a pressure, and/or the like. The electronic device EA of an embodiment may detect the user's input through the active region ED-AA, and may respond to the detected input signal. Also, the electronic device DD may detect the user's inputs applied to a side surface or a rear surface of the electronic device EA according to the design of the provided electronic device EA, but is not limited to a specific embodiment.

Referring to FIGS. 2 and 3, the electronic device EA of an embodiment may include a display module DM, the window member WM, and a housing HAU. In an embodiment, the window member WM and the housing HAU may be combined to form the exterior of the electronic device EA.

In the electronic device EA of an embodiment, the window member WM may include an optically clear insulating material. The window member WM may be a glass substrate or polymer substrate. For example, the window member WM may include a tempered glass substrate subjected to a tempered treatment. The window member WM may correspond to the uppermost layer of the electronic device EA.

In some embodiments, the window member WM in the electronic device EA of an embodiment may be divided into a transmission part TA and a bezel part BZA. The transmission part TA may correspond to the active region AA of the display module DM, and the bezel part BZA may correspond to a peripheral region NAA of the display module DM.

The front surface of the window member WM including the transmission part TA and the bezel part BZA corresponds to the front surface of the electronic device EA. A user may view an image provided through the transmission part TA corresponding to the front surface of the electronic device EA.

The bezel part BZA may define the shape of the transmission part TA. The bezel part BZA may be adjacent to the transmission part TA, and may be around (e.g., may surround) the transmission part TA. However, the embodiment of the present disclosure is not limited to the illustrated one, and the bezel part BZA may be adjacent to only one side of the transmission part TA, and a part thereof may not be provided.

A part of the electronic device EA viewed through the bezel part BZA in the electronic device EA of an embodiment may have lower light transmittance than a part viewed through the transmission part TA. In some embodiments, the bezel part BZA in the electronic device EA of an embodiment may be viewed as a part having a set or predetermined color.

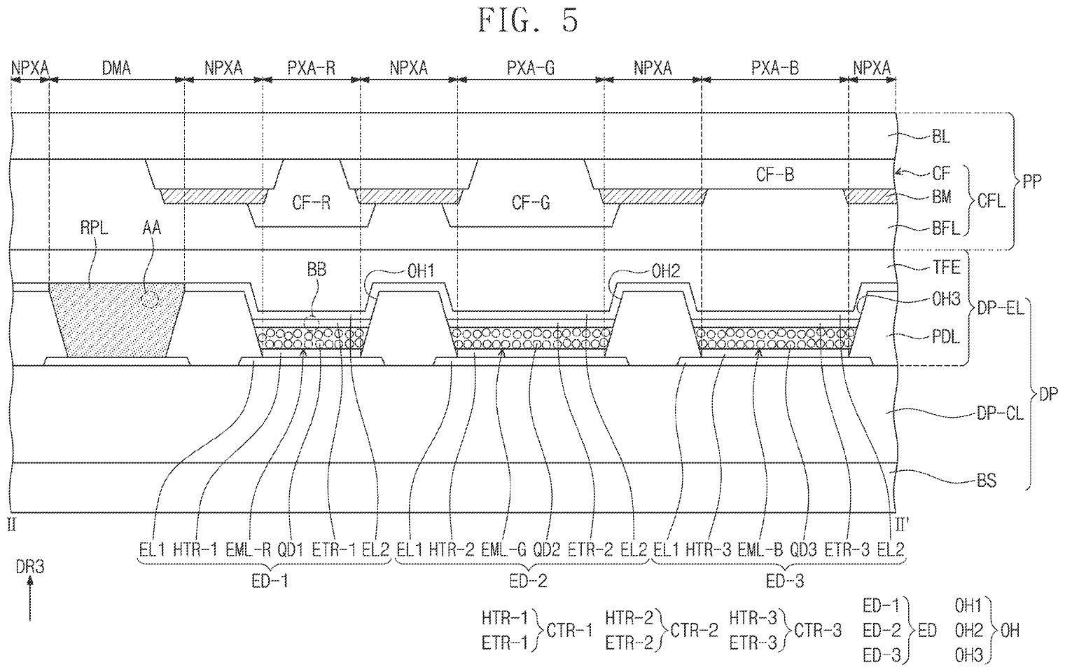

In the electronic device EA of an embodiment, the display module DM may include a display panel DP, and an optical member PP on the display panel DP. The display panel DP may include a display element layer DP-EL. The display element layer DP-EL may include the light emitting elements ED-1, ED-2, and ED-3 (see FIG. 5).

The display panel DP may be a light emitting display panel. For example, the display panel DP may be a quantum dot light emitting display panel including a quantum dot light emitting element.

The display panel DP may include a base substrate BS, a circuit layer DP-CL on the base substrate BS, and the display element layer DP-EL on the circuit layer DP-CL.

The base substrate BS may be a member that provides a base surface on which the display element layer DP-EL is disposed. The base substrate BS may be a glass substrate, a metal substrate, a plastic substrate, etc. However, this is merely an example, and the embodiment of the present disclosure is not limited thereto. For example, the base substrate BS of an embodiment may be an inorganic layer, an organic layer, or an organic/inorganic composite material layer. The base substrate BS may be a flexible substrate which is bendable or foldable.

In an embodiment, the circuit layer DP-CL is on the base substrate BS, and the circuit layer DP-CL may include a plurality of transistors. Each of the transistors may include a control electrode, an input electrode, and an output electrode. For example, the circuit layer DP-CL may include a switching transistor and a driving transistor for driving the light emitting elements ED-1, ED-2, and ED-3 of the display element layer DP-EL.

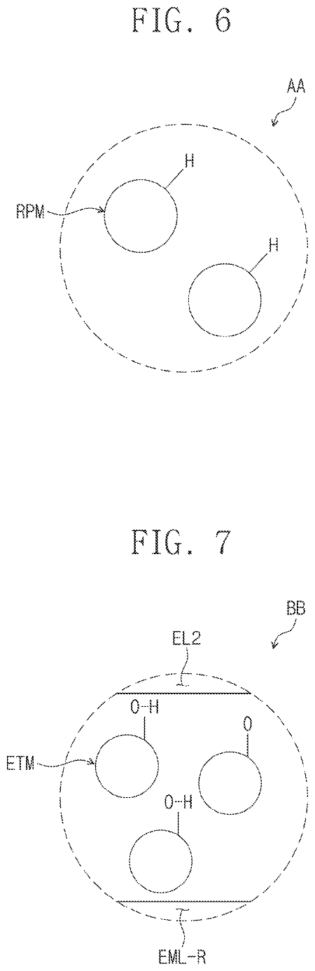

FIG. 4 is a plan view illustrating a portion of a display module according to an embodiment. FIG. 5 is a cross-sectional view of a display module of an embodiment. FIG. 6 is an enlarged view illustrating a portion of a reduction preventing layer according to an embodiment. FIG. 7 is an enlarged view illustrating a portion of an electron transport region according to an embodiment. FIG. 4 is a plan view illustrating a region DD′ of FIG. 2. FIG. 5 is a cross-sectional view taken along line II-II′ of FIG. 4. FIG. 6 is an enlarged view corresponding to AA indicated in FIG. 5. FIG. 7 is an enlarged view corresponding to BB indicated in FIG. 5.

Referring to FIGS. 4 to 7, the display module DM may contain a plurality of light emitting elements ED-1, ED-2, and ED-3. In some embodiments, the module DM of an embodiment may include a display panel DP containing the plurality of light emitting elements ED-1, ED-2, and ED-3, and an optical member PP on the display panel DP. In some embodiments, in the display module DM of an embodiment, the optical member PP may not be provided.

In the display module DM, according to an embodiment, a dummy region DMA and a plurality of light emitting regions PXA-R, PXA-G, and PXA-B may be disposed in the active region AA. The light emitting regions PXA-R, PXA-G, and PXA-B may be regions in which light generated by the respective light emitting elements ED-1, ED-2, and ED-3 is emitted. The light emitting regions PXA-R, PXA-G, and PXA-B may be spaced apart from each other (separated from each other) on a plane (e.g., in a plan view). The dummy region DMA may correspond to a part in which a reduction preventing layer RPL is disposed.

Non-light emitting regions NPXA may be between the light emitting regions PXA-R, PXA-G, and PXA-B and between the dummy region DMA and the light emitting regions PXA-R, PXA-G, and PXA-B. Each of the light emitting regions PXA-R, PXA-G, and PXA-B, and the dummy region DMA and the light emitting regions PXA-R, PXA-G, and PXA-B may be distinguished by the non-light emitting regions NPXA. The non-light emitting regions NPXA may be around (e.g., may surround) each of the light emitting regions PXA-R, PXA-G, and PXA-B, and the dummy region DMA.

In an embodiment, the area of the plurality of light emitting regions PXA-R, PXA-G, and PXA-B, and the dummy region DMA may all be the same or different from each other (i.e., one or more areas may be the same or different). The first light emitting region PXA-R and the dummy region DMA may have the same area, and the second light emitting region PXA-G and the third light emitting region PXA-B may have the same area. Each area of the first light emitting region PXA-R and the dummy region PXA may be smaller than each area of the second light emitting region PXA-G and the third light emitting region PXA-B. In this embodiment, the areas may refer to areas when viewed on a plane (e.g., in a plan view) defined by the first direction axis DR1 and the second direction axis DR2.

However, the embodiment is not limited thereto, and the light emitting regions PXA-R, PXA-G, and PXA-B may have the same area as each other, or the light emitting regions PXA-R, PXA-G, and PXA-B may be provided in a different area ratio from those illustrated in FIG. 4.

The light emitting regions PXA-R, PXA-G, and PXA-B may be divided into a plurality of groups according to the color of light generated from the light emitting elements ED-1, ED-2, and ED-3. In the display module DM of an embodiment illustrated in FIGS. 4 and 5, three light emitting regions PXA-R, PXA-G, and PXA-B which emit red light, green light, and blue light, respectively are illustrated as an example. For example, the display module DM of an embodiment may include the red light emitting region PXA-R, the green light emitting region PXA-G, and the blue light emitting region PXA-B that are separated from each other.

In some embodiments, the light emitting regions PXA-R, PXA-G, and PXA-B may emit different color light from the red light, green light, and blue light, or may have a different plane shape from the illustrated shape.

Referring to FIG. 4, the red light emitting regions PXA-R and the dummy region DMA may be alternately arranged along the direction of the first direction axis DR1 to constitute a first group PXG1. The green light emitting regions PXA-G may be arranged to be spaced apart (separated from each other) along the first direction axis DR1 to constitute a second group PXG2. In some embodiments, the blue light emitting regions PXA-B may be arranged to be spaced apart (separated from each other) along the direction of the first direction axis DR1 to constitute a third group PXG3.

The first group PXG1 to the third group PXG3 may be sequentially arranged in the direction of the second direction axis DR2. Each of the first group PXG1 to the third group PXG3 may be provided in plurality. In an embodiment illustrated in FIG. 4, the first group PXG1, the second group PXG2, the third group PXG3, and the second group (another second ground) PXG2 form one repeating unit along the direction of the second direction axis DR2, and the repeating units may be repeatedly arranged in the direction of the second direction axis DR2.

In an embodiment, one green light emitting region PXA-G may be disposed to be spaced apart from (separated from) one red light emitting region PXA-R or one blue light emitting region PXA-B in the direction of the fourth direction axis DR4. The direction of the fourth direction axis DR4 may be a direction between the direction of the first direction axis DR1 and the direction of the second direction axis DR2.

In some embodiments, the dummy region DMA may be disposed to be spaced apart from each of the light emitting regions PXA-R, PXA-G, and PXA-B. The dummy region DMA may be adjacent to the first light emitting region PXA-R in the direction of the first direction axis DR1. The dummy region DMA may be adjacent to the second light emitting region PXA-G in the direction of the second direction axis DR2.

The dummy region DMA may be in the first group PXAG1. However, this is merely an example, and the embodiment of the present disclosure is not limited thereto. For example, the dummy region DMA may be only in the second group PXAG2, or only in the third group PXAG3, or in at least two selected among the first group PXAG1 to third group PXAG3.

The arrangement structure of the light emitting regions PXA-R, PXA-G, and PXA-B illustrated in FIG. 4 may be referred to as a PENTILE® structure (for example, an RGBG matrix, an RGBG structure, or RGBG matrix structure). PENTILE® is a duly registered trademark of Samsung Display Co., Ltd. However, the arrangement structure of the light emitting regions PXA-R, PXA-G, and PXA-B in the electronic device according to an embodiment is not limited to the arrangement structure illustrated in FIG. 4. For example, in an embodiment, the light emitting regions PXA-R, PXA-G, and PXA-B may have a stripe structure in which a red light emitting region PXA-R, a green light emitting region PXA-G, and a blue light emitting region PXA-B are sequentially and alternately arranged along the first direction axis DR1 or the second direction axis DR2. In some embodiments, in the stripe arrangement structure, the dummy region DMA forms the same line or the same row as the green light emitting region PXA-G to form a single stripe arrangement. However, in an embodiment, the arrangement form, the arrangement ratio, and/or the like of the dummy region DMA and the light emitting regions PXA-R, PXA-G, and PXA-B may be different from those described above.

The plurality of light emitting elements ED-1, ED-2, and ED-3 may emit light beams having wavelengths different from each other. For example, in an embodiment, the display module DM may include a first light emitting element ED-1 that emits red light, which is first light, a second light emitting element ED-2 that emits green light, which is second light, and a third light emitting element ED-3 that emits blue light, which is third light. However, the embodiment is not limited thereto, and the first to the third light emitting elements ED-1, ED-2, and ED-3 may emit light beams in substantially the same wavelength range or at least one light emitting element emits light having a wavelength different from those of the others.

Each of the light emitting elements ED-1, ED-2, and ED-3 may include a first electrode EL1, a second electrode EL2 on the first electrode EL1, a respective one selected from hole transport regions HTR-1, HTR-2, and HTR-3 between the first electrode EL1 and the second electrode EL2. Here, respective emission layers EML-R, EML-G, and EML-B are disposed between the hole transport regions HTR-1, HTR-2, and HTR-3 and the second electrode EL2, and respective electron transport regions ETR-1, ETR-2, and ETR-3 are disposed between the emission layers EML-R, EML-G, and EML-B and the second electrode EL2.

The first electrode EL1 may be provided by being patterned corresponding to the light emitting regions PXA-R, PXA-G, and PXA-B. However, this is merely an example, and the embodiment of the present disclosure is not limited thereto, and the first electrode EL1 may be provided in a single layer to overlap the entire light emitting regions PXA-R, PXA-G, and PXA-B.

The first electrode EL1 may be formed of a metal material, a metal alloy, or a conductive compound. The first electrode EL1 may be an anode or a cathode. However, the embodiment of the present disclosure is not limited thereto. In some embodiments, the first electrode EL1 may be a pixel electrode or a detection electrode. The first electrode EL1 may be a transmissive electrode, a transflective electrode, or a reflective electrode. When the first electrode EL1 is the transmissive electrode, the first electrode EL1 may include a transparent metal oxide such as indium tin oxide (ITO), indium zinc oxide (IZO), zinc oxide (ZnO), and/or indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca, LiF/Al, Mo, Ti, W, one or more compounds thereof, or one or more mixtures thereof (e.g., a mixture of Ag and Mg).

The second electrode EL2 may be a common electrode. For example, the second electrode EL2 may be provided in a common layer in the light emitting elements ED-1, ED-2, and ED-3. The second electrode EL2 may be a cathode or an anode, but the embodiment of the present disclosure is not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc. When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, or one or more compounds or mixtures thereof (e.g., AgMg, AgYb, or MgAg).

The hole transport region HTR may be on the upper portion of the first electrode EL1. The hole transport region HTR may be disposed by being patterned in each of the light emitting elements ED-1, ED-2, and ED-3. The hole transport region HTR may be between the emission layers EML-R, EML-G, and EML-B and may be provided by being divided by a pixel defining film PDL. However, this is merely an example, and the embodiment of the present disclosure is not limited thereto, and the hole transport region HTR may be provided in a single layer to overlap all the light emitting elements ED-1, ED-2, and ED-3.

The hole transport region HTR may have a single layer formed of a single material, a single layer formed of a plurality of different materials, or a multilayer structure including a plurality of layers formed of a plurality of different materials. For example, the hole transport region HTR may have a single layer structure of the hole injection layer or the hole transport layer, or may have a single layer structure formed of a hole injection material and a hole transport material. The hole transport region HTR may include a hole transport layer and further include a hole injection layer.

The electron transport region ETR may be on the upper portion of the hole transport region HTR (e.g., the electron transport region ETR may be on the emission layers EML-R, EML-G, and EML-B). The electron transport region ETR may be disposed by being patterned in each of the light emitting elements ED-1, ED-2, and ED-3. However, this is merely an example, and the embodiment of the present disclosure is not be limited thereto, and the electron transport region ETR may be provided in a single layer to overlap all the light emitting elements ED-1, ED-2, and ED-3.

The electron transport region ETR may have a single layer formed of a single material, a single layer formed of a plurality of different materials, or a multilayer structure including a plurality of layers formed of a plurality of different materials. For example, the electron transport region ETR may have a single layer structure of an electron injection layer or an electron transport layer, and may have a single layer structure formed of an electron injection material and an electron transport material. In some embodiments, the electron transport region ETR may have a single layer structure formed of a plurality of different materials, or may further include a plurality of layers sequentially stacked in the thickness direction.

A first emission layer EML-R of the first light emitting element ED-1 may include a first quantum dot QD1. The first quantum dot QD1 may emit blue light that is a first light. A second emission layer EML-G of the second light emitting element ED-2 and a third emission layer EML-B of the third light emitting element ED-3 may include a second quantum dot QD2 and a third quantum dot QD3, respectively. The second quantum dot QD2 and the third quantum dot QD3 may emit green light that is a second light, and a red light that is a third light, respectively.

In an embodiment, the first light may be light having a wavelength region of about 625 nm to about 675 nm, the second light may be light having a wavelength region of about 500 nm to about 570 nm, and the third light may be light having a wavelength region of about 410 nm to about 480 nm.

The quantum dots QD1, QD2, and QD3 included in the emission layer EML of an embodiment may be selected from among a Group II-VI compound, a Group III-VI compound, a Group I-III-VI compound, a Group III-V compound, a Group III-II-V compound, a Group I-IV-VI compound, a Group IV element, a Group IV compound, and one or more combinations thereof.

The Group II-VI compound may be selected from the group including (e.g., consisting of) a binary compound selected from the group including (e.g., consisting of) CdSe, CdTe, CdS, ZnS, ZnSe, ZnTe, ZnO, HgS, HgSe, HgTe, MgSe, MgS, and one or more compounds or mixtures thereof, a ternary compound selected from the group including (e.g., consisting of) CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and one or more compounds or mixtures thereof, and a quaternary compound selected from the group including (e.g., consisting of) HgZnTeS, CdZnSeS, CdZnSeTe, CdZnSTe, CdHgSeS, CdHgSeTe, CdHgSTe, HgZnSeS, HgZnSeTe, HgZnSTe, and one or more compounds or mixtures thereof.

The Group III-VI compound may include a binary compound such as In₂S₃ or In₂Se₃, a ternary compound such as InGaS₃ or InGaSe₃, or one or more combinations thereof.

The Group I-III-VI compound may be selected from a ternary compound selected from the group including (e.g., consisting of) AgInS, AgInS₂, CuInS, CuInS₂, AgGaS₂, CuGaS₂ CuGaO₂, AgGaO₂, AgAlO₂, and one or more compounds or mixtures thereof, and/or a quaternary compound such as AgInGaS₂ or CuInGaS₂ (the quaternary compound may be used alone or in combination with any of the foregoing compounds or mixtures; and the quaternary compound may also be combined with other quaternary compounds).

The Group III-V compound may be selected from the group including (e.g., consisting of) a binary compound selected from the group including (e.g., consisting of) GaN, GaP, GaAs, GaSb, AlN, AlP, AlAs, AlSb, InN, InP, InAs, InSb, and one or more compounds or mixtures thereof, a ternary compound selected from the group including (e.g., consisting of) GaNP, GaNAs, GaNSb, GaPAs, GaPSb, AlNP, AlNAs, AlNSb, AlPAs, AlPSb, InGaP, InAIP, InNP, InNAs, InNSb, InPAs, InPSb, and one or more compounds or mixtures thereof, and a quaternary compound selected from the group including (e.g., consisting of) GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and one or more compounds or mixtures thereof. In some embodiments, the Group III-V compound may further include a Group II metal. For example, InZnP, etc. may be selected as a Group III-II-V compound.

The Group IV-VI compound may be selected from the group including (e.g., consisting of) a binary compound selected from the group including (e.g., consisting of) SnS, SnSe, SnTe, PbS, PbSe, PbTe, and one or more compounds or mixtures thereof, a ternary compound selected from the group including (e.g., consisting of) SnSeS, SnSeTe, SnSTe, PbSeS, PbSeTe, PbSTe, SnPbS, SnPbSe, SnPbTe, and a mixture thereof, and a quaternary compound selected from the group including (e.g., consisting of) SnPbSSe, SnPbSeTe, SnPbSTe, and one or more compounds or mixtures thereof. The Group IV element may be selected from the group including (e.g., consisting of) Si, Ge, and one or more compounds or mixtures thereof. The Group IV compound may be a binary compound selected from the group including (e.g., consisting of) SiC, SiGe, and one or more compounds or mixtures thereof.

In this embodiment, a binary compound, a ternary compound, or a quaternary compound may be present in a particle form with a substantially uniform concentration distribution, or may be present in substantially the same particle form with a partially different concentration distribution. In some embodiments, the quantum dot may have a core/shell structure in which one quantum dot surrounds or is around the other quantum dot. For example, the quantum dot may have the core/shell structure in which the first quantum dot QD1 surrounds the second quantum dot QD2 or the third quantum dot QD3, the core/shell structure in which the second quantum dot QD2 surrounds the first quantum dot QD1 or the third quantum dot QD3, or the core/shell structure in which the third quantum dot QD3 surrounds the first quantum dot QD1 or the second quantum dot QD2. The core/shell structure may have a concentration gradient in which the concentration of elements present in the shell decreases toward the core.

In some embodiments, the quantum dot may have the above-described core/shell structure including a core containing nanocrystals and a shell around (e.g., surrounding) the core. The shell of the quantum dot may serve as a protection layer to prevent or reduce the chemical deformation of the core to maintain semiconductor properties, and/or a charging layer to impart electrophoresis properties to the quantum dot. The shell may be a single layer or a multilayer. An example of the shell of the quantum dot may include a metal or non-metal oxide, a semiconductor compound, or one or more combinations thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, or a ternary compound such as MgAl₂O₄, CoFe₂O₄, NiFe₂O₄, or CoMn₂O₄, but the embodiment of the present disclosure is not limited thereto.

Also, the semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but the embodiment of the present disclosure is not limited thereto.

The quantum dots QD1, QD2, and QD3 each may have a full width of half maximum (FWHM) of a light emission wavelength spectrum of about 45 nm or less, about 40 nm or less, or about 30 nm or less, and color purity or color reproducibility may be improved in the above ranges. In some embodiments, light emitted through such quantum dots QD1, QD2, and QD3 is emitted in all directions so that a wide viewing angle may be improved (increased).

Each form of the quantum dots QD1, QD2, and QD3 is not limited as long as it is a form generally utilized/generally available in the art. For example, a quantum dot in the form of a substantially spherical, pyramidal, multi-arm, or cubic nanoparticles, nanotubes, nanowires, nanofibers, nanoplate particles, etc. may be utilized.

The quantum dots QD1, QD2, and QD3 may control the color of emitted light according to the particle size, and thus the quantum dots QD1, QD2, and QD3 may have one or more suitable luminescent colors such as blue, red, and/or green. As the particle size of the quantum dots QD1, QD2, and QD3 becomes smaller, the quantum dots QD1, QD2, and QD3 may emit light in the short wavelength region. For example, in the quantum dots QD1, QD2, and QD3 having the same core, the particle size of a quantum dot emitting green light may be smaller than the particle size of a quantum dot emitting red light. In some embodiments, in the quantum dots QD1, QD2, and QD3 having the same core, the particle size of a quantum dot emitting blue light may be smaller than the particle size of a quantum dot emitting green light. However, the embodiment of the present disclosure is not limited thereto, and even in the quantum dots QD1, QD2, and QD3 having the same core, the particle size may be adjusted according to forming-materials and thickness of a shell.

In some embodiments, when quantum dots QD1, QD2, and QD3 have one or more suitable luminescent colors such as blue, red, and green, the quantum dots QD1, QD2, and QD3 having different luminescent colors may have different core materials.

In an embodiment, the first to third quantum dots QD1, QD2, and QD3 may have different sizes (e.g., diameters). For example, the first quantum dot QD1 utilized in the first light emitting element ED-1 emitting light in a relatively short wavelength range may have a relatively smaller average size than the second quantum dot QD2 of the second light emitting element ED-2 and the third quantum dot QD3 of the third light emitting element ED-3 each emitting light in a relatively long wavelength region.

In some embodiments, in the present disclosure, the average size refers to the arithmetic mean of the sizes of a plurality of quantum dot particles. In some embodiments, the size of the quantum dot particle may be the average value of the width of the quantum dot particle in a cross section.

The relationship of the average sizes of the first to third quantum dots QD1, QD2, and QD3 is not limited to the above limitations. For example, FIG. 5 illustrates that the first to third quantum dots QD1, QD2, and QD3 are different in size from one another, but the first to third quantum dots QD1, QD2, and QD3 included in the light emitting elements ED-1, ED-2, and ED-3 may be similar in size. In some embodiments, the average size of two quantum dots selected from the first to third quantum dots QD1, QD2, and QD3 may be similar, and the rest (i.e., those that arenot similar) may be different.

In the light emitting elements ED-1, ED-2, and ED-3 of an embodiment, emission layers EML-R, EML-G, and EML-B each may include a host and a dopant. In an embodiment, the emission layers EML-R, EML-G, and EML-B may include quantum dots QD1, QD2, and QD3 as dopant materials. In some embodiments, in an embodiment, the emission layers EML-R, EML-G, and EML-B may further include host materials. In some embodiments, in the light emitting elements ED-1, ED-2, and ED-3 of an embodiment, emission layers EML-R, EML-G, and EML-B may emit fluorescence. For example, quantum dots QD1, QD2, and QD3 may be utilized as a fluorescent dopant material.

Each of the first to third quantum dots QD1, QD2, and QD3 may have ligands, which may improve dispersibility, bonded to the surface thereof.

Each of the light emitting regions PXA-R, PXA-G, and PXA-B and the dummy region DMA may be a region divided by the pixel defining film PDL. The peripheral regions NPXA may be regions between the adjacent light emitting regions PXA-R, PXA-G, and PXA-B and the dummy region DMA, which correspond to portions of the pixel defining film PDL. In some embodiments, in the disclosure, the light emitting regions PXA-R, PXA-G, and PXA-B may respectively correspond to pixels. The pixel defining film PDL may divide the light emitting elements ED-1, ED-2, and ED-3. The emission layers EML-R, EML-G, and EML-B of the light emitting elements ED-1, ED-2, and ED-3 may be disposed in openings OH defined in the pixel defining film PDL and separated from each other. In an embodiment, the first emission layer EML-R of the first light emitting element ED-1 may be disposed in a first opening OH1, the second emission layer EML-G of the second light emitting element ED-2 may be disposed in a second opening OH2, and the third emission layer EML-B of the third light emitting element ED-3 may be disposed in a third opening OH3.

The pixel defining film PDL may be formed of a polymer resin. For example, the pixel defining film PDL may include a polyacrylate-based resin or a polyimide-based resin. In some embodiments, the pixel defining film PDL may further include an inorganic material in addition to the polymer resin. In some embodiments, the pixel defining film PDL may include a light absorbing material or a black pigment and/or a black dye. The pixel definition layer PDL formed to contain a black pigment and/or a black dye may form a black pixel definition layer. Carbon black and/or the like may be utilized as the black pigment and/or black dye in formation of the pixel definition layer PDL, but the embodiment is not limited thereto.

Also, the pixel defining film PDL may be formed of an inorganic material. For example, the pixel defining films PDL may include silicon nitride (SiNx), silicon oxide (SiOx), silicon oxynitride (SiOxNy), silicon nitride oxide (SiNxOy), etc. The pixel defining film PDL may define the light emitting regions PXA-R, PXA-G, and PXA-B and the dummy region DMA. The light emitting regions PXA-R, PXA-G, and PXA-B and the dummy region DMA and the peripheral regions NPXA may be divided by the pixel defining film PDL.

The hole transport regions HTR-1, ETR-2, and HTR-3 and the electron transport regions ETR-1, ETR-2, and ETR-3 included in the light emitting elements ED-1, ED-2, and ED-3, respectively, may be disposed and divided in the openings OH1, OH2, and OH3 defined in the pixel defining film PDL.

For example, a first hole transport region HTR-1 and a first electron transport region ETR-1 included in the first light emitting element ED-1 may be adjacent to the first emission layer EML-R, and may be disposed by being patterned in a first opening OH1 in which the first emission layer EML-R is disposed. A second hole transport region HTR-2 and a second electron transport region ETR-2 included in the second light emitting element ED-2 may be adjacent to the second emission layer EML-G, and may be disposed by being patterned in a second opening OH2 in which the second emission layer EML-G is disposed. A third hole transport region HTR-3 and a third electron transport region ETR-3 included in the third light emitting element ED-3 may be adjacent to the third emission layer EML-B, and may be disposed by being patterned in a third opening OH3 in which the third emission layer EML-B is disposed. However, the embodiment of the present disclosure is not limited thereto, and the hole transport regions HTR-1, HTR-2, and HTR-3 and the electron transport regions ETR-1, ETR-2, and ETR-3 may be provided in a common layer commonly disposed in pixel regions PXA-R, PXA-G, and PXA-B and the peripheral regions NPXA.

In an embodiment, the hole transport regions HTR-1, HTR-2, and HTR-3 and the electron transport regions ETR-1, ETR-2, and ETR-3 may be provided in the openings OH1, OH2, and OH3, respectively, defined in the pixel defining film PDL through a printing process.

The encapsulation layer TFE may cover the light emitting elements ED-1, ED-2, and ED-3. The encapsulation layer TFE may seal the display device layer DP-EL. The encapsulation layer TFE may be a thin film encapsulation layer. The encapsulation layer TFE may be formed by laminating one layer or a plurality of layers. The encapsulation layer TFE includes at least one insulation layer. The encapsulation layer TFE according to an embodiment may include at least one inorganic film (hereinafter, an encapsulation-inorganic film). The encapsulation layer TFE according to an embodiment may also include at least one organic film (hereinafter, an encapsulation-organic film) and at least one encapsulation-inorganic film.

The encapsulation-inorganic film protects the display element layer DP-EL from moisture/oxygen, and the encapsulation-organic film protects the display element layer DP-EL from foreign substances such as dust particles. The encapsulation-inorganic film may include silicon nitride, silicon oxynitride, silicon oxide, titanium oxide, aluminum oxide, and/or the like, but the embodiment of the present disclosure is not limited thereto. The encapsulation-organic film may include an acrylic-based compound, an epoxy-based compound, and/or the like. The encapsulation-organic film may include a photopolymerizable organic material, but the embodiment of the present disclosure is not limited thereto.

The encapsulation layer TFE may be on the second electrode EL2 and may be disposed so as to fill the openings OH1, OH2, and OH3.

In the display module DM of an embodiment illustrated in FIG. 5, the thicknesses of the emission layers EML-R, EML-G, and EML-B of the first to third light emitting elements ED-1, ED-2, and ED-3 are illustrated to be similar to one another, but the embodiment of the present disclosure is not limited thereto. For example, in an embodiment, the thicknesses of the emission layers EML-R, EML-G, and EML-B of the first to third light emitting elements ED-1, ED-2, and ED-3 may be different from one another. In some embodiments, each thickness of the hole transport regions HTR-1, HTR-2, and HTR-3 and the electron transport regions ETR-1, ETR-2, and ETR-3 of the first to third light emitting elements ED-1, ED-2, and ED-3 may also be different from one another.

Referring to FIG. 7, the electron transport region ETR may contain a metal oxide ETM (Electron Transport Material). The metal oxide ETM may include an oxygen vacancy on the surface thereof. The metal oxide ETM of an embodiment may be represented by Formula 3:

M₁₍ₓ₎O_{(y)} Formula 3

In Formula 3, M₁ may be any one selected from among Zn, Ti, Zr, Sn, W, Ta, Ni, Mo, and Cu. x and y may each independently be an integer from 1 to 5. x and y may be a relative number of M₁ and O respectively contained in the metal oxide ETM. For example, when x is 1 and y is 1, the metal oxide ETM may have the number ratio of M₁ and O of 1:1, and when x is 1 and y is 2, the metal oxide ETM may have the number ratio of M₁ and O of 1:2. For example, the metal oxide ETM may be any one selected from among ZnO, MoO₃, NiOₓ, TiO₂, SnO₂, and Cu₂O. However, this is merely an example, and the embodiment of the present disclosure is not limited thereto.

The metal oxide ETM of an embodiment may be represented by Formula 4:

Zn_{(1-z)}M_{2(z)}O Formula 4

In Formula 4, M2 may be any one selected from among Mg, Co, Ni, Zr, Mn, Sn, Y, and Al. z may be 0 to 0.5. When z is 0, the metal oxide ETM represented by Formula 4 may not include (e.g., may exclude) M₂ and may have the number ratio of Zn and O of 1:1. When z is 0.5, the metal oxide ETM represented by Formula 4 may have the number ratio of Zn, M₂, and O of 1:1:2. For example, the metal oxide ETM may be ZnMgO. However, this is merely an example, and the embodiment of the present disclosure is not limited thereto.

Referring to FIG. 6, the reduction preventing layer RPL may contain a reduction preventing agent RPM (Reduction Preventing Material). The reduction preventing agent RPM may include a hydrogen atom bonded on the surface thereof. The reduction preventing agent RPM may provide a hydrogen atom to the electron transport region ETR. The reduction preventing agent RPM may be represented by Formula 1 or Formula 2.

In an embodiment, the reduction preventing agent RPM may include a hydrogen atom at the end thereof. The reduction preventing agent RPM may be an acidic material according to Brønsted-Lowry definition of acids and bases. For example, the reduction preventing agent RPM may provide the hydrogen atom at the end (of the agent) thereof to a relatively basic material.

In an embodiment, the metal oxide ETM may include an oxygen atom on the surface thereof. The metal oxide ETM may be a basic material according to Brønsted-Lowry definition of acids and bases. For example, a hydrogen atom may be provided from a relatively acidic material to the oxygen atom at the end of the metal oxide ETM. For example, the metal oxide ETM may include an oxygen vacancy on the surface thereof.

The oxygen vacancy on the surface of the metal oxide ETM may cause an electron trap effect. As the metal oxide ETM has a decrease in the proportion of the oxygen vacancy on the surface thereof, the electron trap of the metal oxide ETM may be reduced. As the electron trap of the metal oxide ETM is reduced, the electron transport function of the electron transport region ETR containing the metal oxide ETM may increase. For example, as the proportion of the oxygen vacancy on the surface of the metal oxide ETM is smaller, the electron transport function of the electron transport region ETR may increase.

The oxygen vacancy on the surface of the metal oxide ETM of an embodiment may be removed by the hydrogen atom of the reduction preventing agent RPM. For example, in an embodiment, the metal oxide ETM may be provided with a hydrogen atom from the reduction preventing agent RPM. The metal oxide ETM of an embodiment may have a smaller proportion of the oxygen vacancy on the surface of the metal oxide ETM than the case of no effects from the reduction preventing agent RPM. Accordingly, the metal oxide ETM of an embodiment may have a decrease in the electron trap and an increase in the electron transport function of the electron transport region ETR containing the metal oxide ETM compared to a comparative example of no effects from the reduction preventing agent RPM. For example, the electronic device EA of an embodiment includes the reduction preventing or reducing layer RPL containing the reduction preventing or reducing agent RPM, thereby the electron transport function of the electron transport region ETR containing the metal oxide ETM may be improved, and thus the luminous efficiency of the electronic device EA may be improved.

In an embodiment, the reduction preventing agent RPM may include a carboxyl group or a hydroperoxyl group. The reduction preventing agent RPM may be represented by Formula 1 or Formula 2:

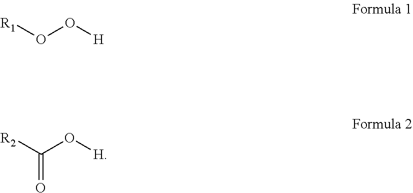

In Formula 1, R₁ may be a substituted or unsubstituted alkyl group having 1 to 20 carbon atoms, or a substituted or unsubstituted aryl group having 6 to 30 ring-forming carbon atoms. In Formula 2, R₂ may be a substituted or unsubstituted alkyl group having 1 to 20 carbon atoms, or a substituted or unsubstituted aryl group having 6 to 30 ring-forming carbon atoms.

The reduction preventing agent RPM may be represented by any one selected from among compounds in Compound Group 1:

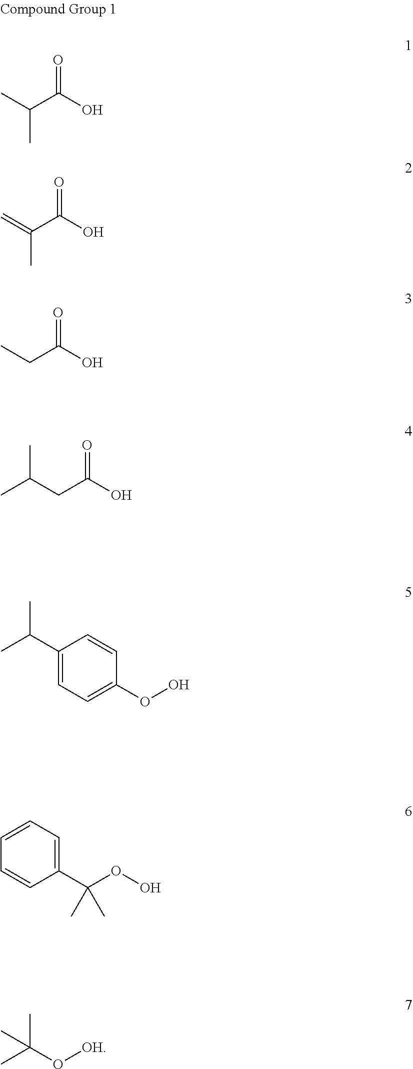

In the disclosure, the term “substituted or unsubstituted” may refer to substituted or unsubstituted with at least one substituent selected from the group including (e.g., consisting of) a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In some embodiments, each of the substituents exemplified above may be substituted or unsubstituted. For example, a biphenyl group may be interpreted as an aryl group or a phenyl group substituted with a phenyl group.

Referring to FIGS. 3 and 5, the display module DM of an embodiment may further include the optical member PP. The optical member PP may block or reduce the external light provided from the outside of the display module DM to the display panel DP. The optical member PP may block or reduce part of external light. The optical member PP may function to prevent or reduce reflection for minimizing or reducing the reflection by the external light.

In an embodiment illustrated in FIG. 5, the optical member PP may include a base substrate BL and a light control layer CFL. The display module DM of an embodiment may further include the light control layer CFL on the light emitting elements ED-1, ED-2, and ED-3 of the display panel DP.

The base substrate BL may be a member configured to provide a base surface on which the light control layer CFL and/or the like is disposed. The base substrate BL may be a glass substrate, a metal substrate, a plastic substrate, etc. However, the embodiment of the present disclosure is not limited thereto, and the base substrate BL may be an inorganic layer, an organic layer, or a composite material layer.

The light control layer CFL may include a light shielding part BM and a color filter part CF. The color filter part CF may include a plurality of filters CF-R, CF-G, and CF-B. For example, the light control layer CFL may include a first filter CF-R transmitting the first light, a second filter CF-G transmitting the second light, and a third filter CF-B transmitting the third light. For example, the first filter CF-R may be a red filter, the second filter CF-G may be a green filter, and the third filter CF-B may be a blue filter.

The filters CF-R, CF-G, and CF-B each may include a polymeric photosensitive resin and a pigment and/or dye. The first filter CF-R may include a red pigment and/or dye, the second filter CF-G may include a green pigment and/or dye, and the third filter CF-B may include a blue pigment and/or dye.

However, the embodiment of the present disclosure is not limited thereto, and the third filter CF-B may not include (e.g., may exclude) a pigment and/or dye. The third filter CF-B may include a polymeric photosensitive resin and may not include (e.g., may exclude) a pigment and/or dye. The third filter CF-B may be transparent. The third filter CF-B may be formed of a transparent photosensitive resin.

The light shielding part BM may be a black matrix. The light shielding part BM may include an organic light shielding material or an inorganic light shielding material containing a black pigment and/or dye. The light shielding part BM may prevent or reduce light leakage, and may separate boundaries between the adjacent filters CF-R, CF-G, and CF-B.

The light control layer CFL may further include a buffer layer BFL. For example, the buffer layer BFL may be a protective layer which protects the filters CF-R, CF-G, and CF-B. The buffer layer BFL may be an inorganic material layer containing at least one inorganic material selected from among silicon nitride, silicon oxide, and silicon oxynitride. The buffer layer BFL may be formed of a single layer or a plurality of layers.

In an embodiment illustrated in FIG. 5, the first filter CF-R of the light control layer CFL is illustrated to overlap the second filter CF-G and the third filter CF-B, but the embodiment of the present disclosure is not limited thereto. For example, the first to third filters CF-B, CF-G, and CF-R may be divided by the light shielding part BM and may not overlap one another. In some embodiments, the first to third filters CF-B, CF-G, and CF-R may be disposed corresponding to the blue light emitting region PXA-B, the green light emitting region PXA-G, and the red light emitting region PXA-R, respectively. In the display module DM of an embodiment, the light control layer CFL may not be provided.

The display module DM of an embodiment may include a polarizing layer as the optical member PP instead of the light control layer CFL. The polarizing layer may block or reduce external light provided to the display panel DP from the outside. The polarizing layer may block or reduce a part of external light.

In some embodiments, the polarizing layer may reduce reflected light generated in the display panel DP by external light. For example, the polarizing layer may function to block or reduce reflected light in an embodiment in which light provided from the outside of the display module DM is incident to the display panel DP and exits again. The polarizing layer may be a circularly polarizer having a reflection preventing or reducing function or the polarizing layer may include a linear polarizer and a λ/4 phase retarder. In some embodiments, the polarizing layer may be on the base substrate BL to be exposed or the polarizing layer may be under the base substrate BL.

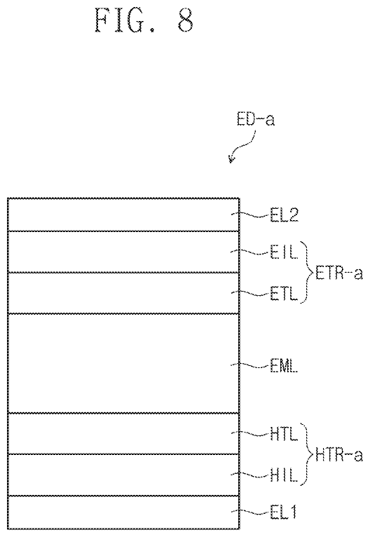

Hereinafter, a light emitting element included in the electronic device of an embodiment will be described in more detail with reference to FIG. 8. The same descriptions as described with reference to FIGS. 1 to 7 may not be described again, and the differences will be primarily described.

FIG. 8 is a cross-sectional view schematically illustrating a light emitting element of an embodiment.

Compared with the light emitting elements illustrated in FIG. 5, FIG. 8 has a difference in that a hole transport region HTR includes a hole injection layer HIL and a hole transport layer HTL, and an electron transport region ETR includes an electron injection layer EIL and an electron transport layer ETL.

Referring to FIG. 8, in a light emitting element ED-a of an embodiment, a hole transport region HTR-a may include a hole injection layer HIL and a hole transport layer HTL. In the light emitting element ED-a of an embodiment, an electron transport region ETR-a may include an electron injection layer EIL and an electron transport layer ETL. The electron transport region ETR-a of an embodiment may include the metal oxide ETM (see e.g., FIG. 7) of an embodiment in at least one layer of the electron injection layer EIL or the electron transport layer ETL. For example, only the electron injection layer EIL may include the metal oxide ETM (see e.g., FIG. 7), or only the electron transport layer ETL may include the metal oxide ETM (see e.g., FIG. 7), or both (e.g., simultaneously) the electron injection layer EIL and the electron transport layer ETL may include the metal oxide ETM (see e.g., FIG. 7).

FIG. 9 is a graph showing a change in luminous efficiency over time for the electronic devices of Example and Comparative Example. In FIG. 9, Example is the electronic device including the reduction preventing layer described with reference to FIGS. 1 to 7. Comparative Example is the electronic device having the same structure as Example except that the reduction preventing layer is not included.

Referring to FIG. 9, it may be seen that the electronic device of Example has a slight decrease in the luminous efficiency over time and the electronic device of Comparative Example has a significant decrease in the luminous efficiency over time. Accordingly, it may be confirmed that the electronic device including the reduction preventing layer has an improved luminous efficiency as compared with the electronic device excluding the reduction preventing layer.

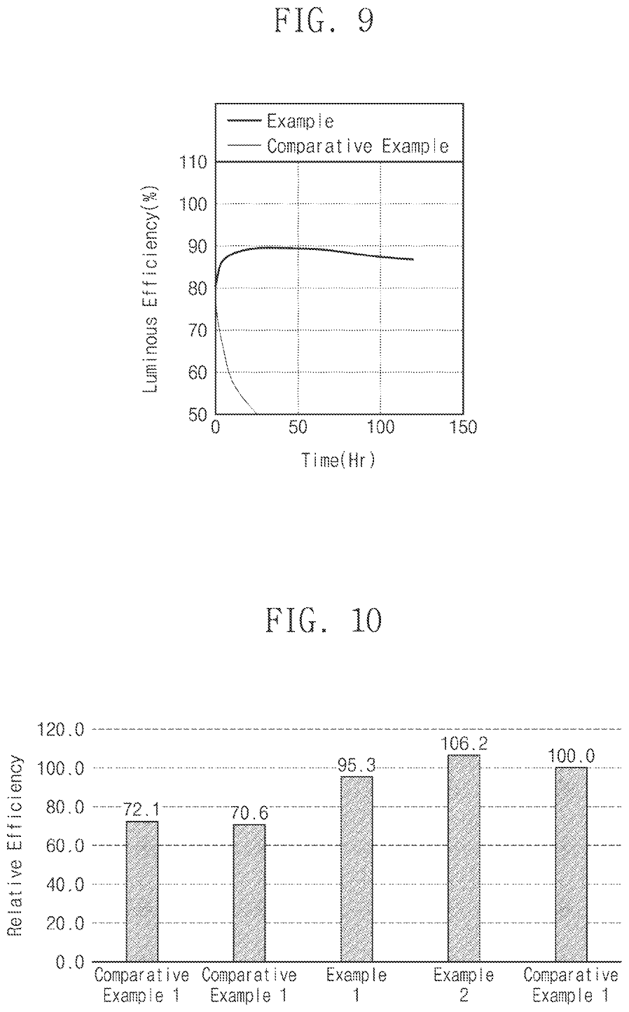

FIG. 10 is a graph showing a relative value of the luminous efficiency versus addition ratio of a reduction preventing agent contained in each of reduction preventing layers of electronic devices of Examples and Comparative Examples. In FIG. 10, Comparative Example 3 shows the luminous efficiency when the light emitting element of the electronic device does not include the electron transport region or reduction preventing layer containing the metal oxide, and drives alone the emission layer including a quantum dot. Comparative Example 1 shows the luminous efficiency when the emission layer is driven in the case in which the electron transport region containing the metal oxide is on the upper portion of the emission layer. Comparative Example 2 shows the luminous efficiency when the reduction preventing layer is included as the electronic devices described in FIGS. 1 to 7, and the reduction preventing agent of the reduction preventing layer is contained in an amount of about 0.01 vol % with respect to a total volume of the reduction preventing layer. Examples 1 and 2 each show the luminous efficiency when the reduction preventing layer is included as the electronic devices described in FIGS. 1 to 7, and the reduction preventing agents of the reduction preventing layers are contained in an amount of about 0.05 vol % and about 0.10 vol %, respectively, with respect to the total volume of the reduction preventing layer.

Referring to FIG. 10, it may be seen that the electronic devices of Examples 1 and 2 have higher relative efficiencies than the electronic devices of Comparative

Examples 1 to 3.

When Comparative Example 1 and Comparative Example 3 are compared, referring to the luminous efficiency, it may be seen that when the electron transport region containing the metal oxide is on the upper portion of the emission layer including a quantum dot, the luminous efficiency is reduced.

When Comparative Example 1 and Comparative Example 2 are compared, it may be seen that when the reduction preventing layer containing about 0.01 vol % of the reduction preventing agent with respect to the total volume of the reduction preventing layer is included, the luminous efficiency of the electronic device is reduced.

When Comparative Example 1, Example 1, and Example 2 are compared, it may be seen that when the reduction preventing layer containing about 0.05 vol % or about 0.10 vol % of the reduction preventing agent with respect to the total volume of the reduction preventing layer is included, the luminous efficiency of the electronic device is reduced. Accordingly, it may be confirmed that when the ratio (e.g., the critical ratio) of the reduction preventing agent added is about 0.05 vol % or more, the luminous efficiency of the electronic device may be improved.

The electronic device of an embodiment includes the reduction preventing layer containing the reduction preventing agent, thereby having excellent or suitable (high) luminous efficiency. For example, the oxygen vacancy on the surface of the metal oxide included in the electron transport region may be removed or reduced by the reduction preventing agent, the electron trap effect of the metal oxide may be reduced, and thus the electron transport function of the electron transport region may be improved. Accordingly, the luminous efficiency of the electronic device including the electron transport region having improved the electron transport function may be improved.

The electronic device of an embodiment includes the reduction preventing layer, thereby the electron transport region has an excellent or suitable electron transport function, and thus the electronic device may have excellent or suitable luminous efficiency.

As used herein, expressions such as “at least one of”, “any one of”, and “selected from”, when preceding a list of elements, modify the entire list of elements and do not modify the individual elements of the list. For example, “at least one of a, b or c”, “any least one of a, b or c”, “at least one selected from a, b and c”, “any one selected from a, b, and c”, etc., may indicate only a, only b, only c, both (e.g., simultaneously) a and b, both (e.g., simultaneously) a and c, both (e.g., simultaneously) b and c, all of a, b, and c, or variations thereof.

In the present disclosure, when particles are spherical, “average size” indicates an average particle diameter, and when the particles are non-spherical, the “average size” indicates a major axis length. The size of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter (or size) is referred to as D50. D50 refers to the average diameter (or size) of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

The use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this disclosure is intended to include all higher numerical limitations subsumed therein. Accordingly, Applicant reserves the right to amend this disclosure, including the claims, to expressly recite any sub-range subsumed within the ranges expressly recited herein.

The electronic device or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the embodiments of the present disclosure have been described, it is understood that the present disclosure should not be limited to these embodiments, but one or more suitable changes and modifications can be made by one ordinary skilled in the art within the spirit and scope of the present disclosure as defined by the following claims and equivalents thereof.

What is claimed is:

1. An electronic device comprising:
first to third light emitting regions; and
a dummy region,
wherein the electronic device comprises:
a base layer; and
a display element layer comprising a pixel defining film on the base layer, first to third light emitting elements which are divided by the pixel defining film and arranged corresponding to the first to third light emitting regions, respectively, and a reduction preventing layer which is disposed corresponding to the dummy region and comprises a reduction preventing agent,
wherein the first to third light emitting elements each comprise:
a first electrode;
a second electrode on the first electrode;
a hole transport region between the first electrode and the second electrode; and
an electron transport region between the hole transport region and the second electrode and comprises a metal oxide, and
wherein:
the first light emitting element comprises a first emission layer comprising a first quantum dot between the hole transport region and the electron transport region;
the second light emitting element comprises a second emission layer comprising a second quantum dot between the hole transport region and the electron transport region; and
the third light emitting element comprises a third emission layer comprising a third quantum dot between the hole transport region and the electron transport region.

2. The electronic device of claim 1, wherein the reduction preventing agent is represented by Formula 1 or Formula 2: 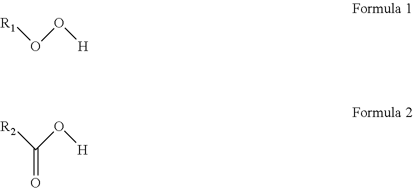
wherein,
in Formula 1, R₁ is a substituted or unsubstituted alkyl group having 1 to 20 carbon atoms, or a substituted or unsubstituted aryl group having 6 to 30 ring-forming carbon atoms, and
in Formula 2, R₂ is a substituted or unsubstituted alkyl group having 1 to 20 carbon atoms, or a substituted or unsubstituted aryl group having 6 to 30 ring-forming carbon atoms.

3. The electronic device of claim 2, wherein the reduction preventing agent is represented by any one selected from among compounds in Compound Group 1:

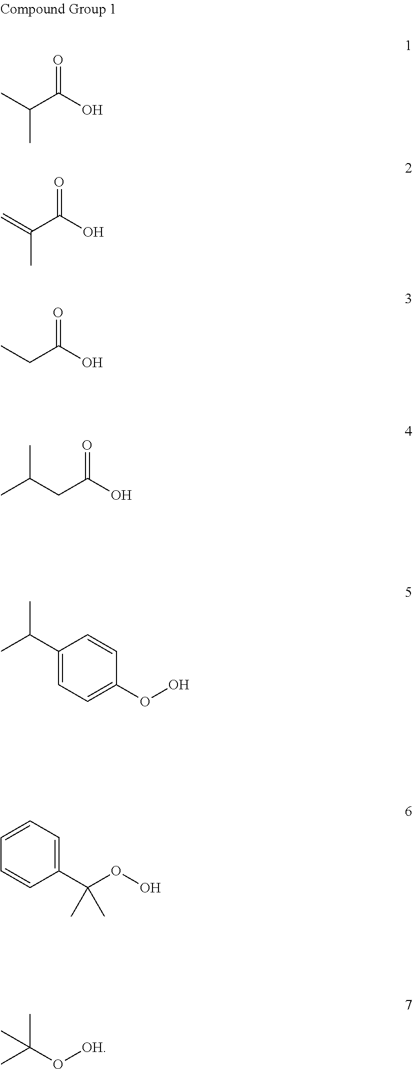

4. The electronic device of claim 1, wherein the metal oxide is represented by Formula 3:
M₁₍ₓ₎O_{(y)} Formula 3
wherein, in Formula 3,
M₁ is any one selected from among Zn, Ti, Zr, Sn, W, Ta, Ni, Mo, and Cu, and
x and y are each independently an integer from 1 to 5.

5. The electronic device of claim 1, wherein the metal oxide is represented by Formula 4:
Zn_{(1-z)}M_{2(z)}O Formula 4
wherein, in Formula 4,
M₂ is any one selected from among Mg, Co, Ni, Zr, Mn, Sn, Y, and Al, and
z is 0 to 0.5.

6. The electronic device of claim 1, wherein the metal oxide comprises at least one of ZnO, ZnMgO, MoO₃, NiOₓ, TiO₂, SnO₂, or Cu₂O.

7. The electronic device of claim 1, wherein, in a plan view, the dummy region is adjacent to the first light emitting region in a first direction, and the dummy region is adjacent to the second light emitting region in a second direction perpendicular to the first direction.

8. The electronic device of claim 1, wherein, in a plan view, the area of the dummy region is smaller than the area of the second light emitting region and is also smaller than the area of the third light emitting region.

9. The electronic device of claim 1, wherein the first emission layer is configured to emit red light, the second emission layer is configured to emit green light, and the third emission layer is configured to emit blue light.

10. The electronic device of claim 9, further comprising a light control layer on the display element layer,
wherein the light control layer comprises:
a first filter which overlaps the first emission layer and is configured to transmit the red light;
a second filter which overlaps the second emission layer and is configured to transmit the green light; and
a third filter which overlaps the third emission layer and is configured to transmit the blue light.

11. The electronic device of claim 1, wherein the reduction preventing layer comprises about 0.05 vol % to about 0.10 vol % of the reduction preventing agent with respect to a total volume of the reduction preventing layer.

12. The electronic device of claim 1, wherein the reduction preventing agent comprises a hydrogen atom at an end of the reduction preventing agent, the metal oxide comprises an oxygen atom on the surface of the metal oxide, and the oxygen atom is bonded to the hydrogen atom.

13. An electronic device comprising:
a base layer; and
a display element layer comprising:
a pixel defining film on the base layer;
a light emitting element divided by the pixel defining film; and
a reduction preventing layer comprising a reduction preventing agent comprising a hydrogen atom,
wherein the light emitting element comprises:
a first electrode;
a second electrode on the first electrode;
a hole transport region between the first electrode and the second electrode,
an emission layer which is between the hole transport region and the second electrode and comprises a quantum dot; and
an electron transport region which is between the emission layer and the second electrode and comprises a metal oxide comprising an oxygen atom on the surface of the metal oxide.

14. The electronic device of claim 13, wherein the reduction preventing agent is represented by Formula 1 or Formula 2: 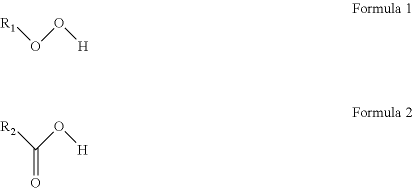
wherein,
in Formula 1, R₁ is a substituted or unsubstituted alkyl group having 1 to 20 carbon atoms, or a substituted or unsubstituted aryl group having 6 to 30 ring-forming carbon atoms, and
in Formula 2, R₂ is a substituted or unsubstituted alkyl group having 1 to 20 carbon atoms, or a substituted or unsubstituted aryl group having 6 to 30 ring-forming carbon atoms.

15. The electronic device of claim 14, wherein the reduction preventing agent is represented by any one selected from among compounds in Compound Group 1:

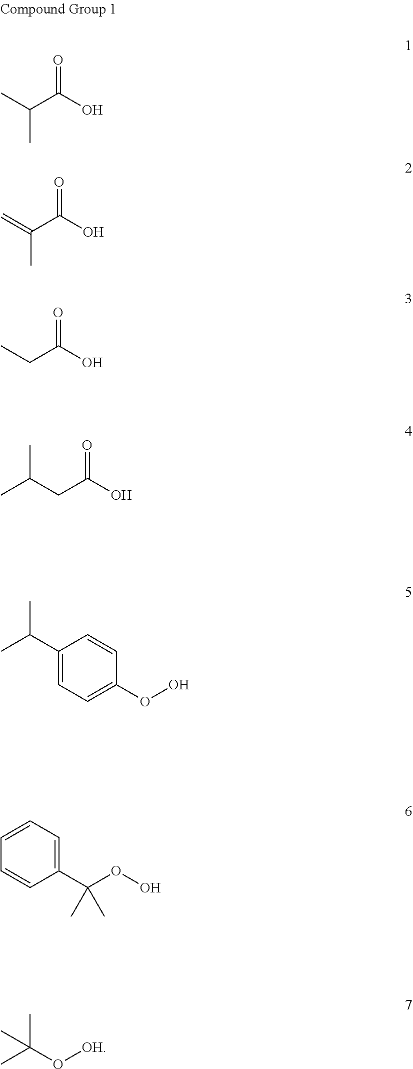

16. The electronic device of claim 13, wherein the metal oxide is represented by Formula 3:
M₁₍ₓ₎O_{(y)} Formula 3
wherein, in Formula 3,
M₁ is any one selected from Zn, Ti, Zr, Sn, W, Ta, Ni, Mo, and Cu, and
x and y are each independently an integer from 0 to 5.

17. The electronic device of claim 13, wherein the metal oxide is represented by Formula 4:
Zn_{(1-z)}M_{2(z)}O Formula 4
wherein, in Formula 4,
M₂ is any one selected from Mg, Co, Ni, Zr, Mn, Sn, Y, and Al, and
z is 0 to 0.5.

18. The electronic device of claim 13, wherein the metal oxide comprises at least one of ZnO, ZnMgO, MoO₃, NiOₓ, TiO₂, SnO₂, or Cu₂O.

19. The electronic device of claim 13, wherein the electron transport region comprises:
an electron transport layer adjacent to the emission layer; and
an electron injection layer on the electron transport layer,
wherein at least one of the electron transport layer or the electron injection layer comprises the metal oxide to which the hydrogen atom is bonded.

20. The electronic device of claim 13, wherein the electron transport region comprises the metal oxide in which the hydrogen atom is bonded to the oxygen atom.
